(19) United States
(12) Patent Application Publication
(10) Pub. No.: US 2019/0381591 A1
(43) Pub. Date: Dec. 19, 2019

(54) MANUFACTURING LINE FOR SOLDERING

(71) Applicant: Endress+Hauser SE+Co. KG, Maulurg (DE)

(72) Inventor: Christoph Hippin, Grenzach-Wyhlen (DE)

(21) Appl. No.: 16/305,431

(22) PCT Filed: May 17, 2017
(86) PCT No.: PCT/EP2017/061806

§ 371 Date: Nov. 29, 2018

(30) Foreign Application Priority Data
May 31, 2016 (DE) 10 2016 110 040.4

(51) Int. Cl. B23K 3/047; B23K 1/00; B23K 1/008; B23K 3/08; H05K 3/34; H05K 3/00

(52) U.S. Cl. CPC B23K 3/0478; B23K 1/0016; B23K 1/008; B23K 2101/36; H05K 3/3494; H05K 3/0085; B23K 3/08

(57) ABSTRACT

The disclosure relates to a manufacturing line for soldered components on a circuit board, comprising a soldering oven including at least two temperature zones having a predetermined temperature profile, a transport apparatus embodied to transport circuit boards through the temperature zones, and a control system, wherein, in at least one of the temperature zones, at least two heating elements are arranged such that a to-be-soldered surface of each circuit board is heated by the heating elements, wherein, in at least one of the temperature zones, at least two air circulators are arranged in the transport direction offset from one another and facing the surface to be soldered, and wherein the control system is configured to control the heating elements and the air circulators such that the to-be-soldered surface of the circuit board is heated according to the predetermined temperature profile.

The invention relates to a manufacturing line for soldering components on at least one surface of a circuit board.

Soldering is a thermal method, with which a material bonded connection is obtained by means of a connection material, or solder, usually in the form of an easily meltable, metal alloy. The present invention relates to reflow soldering and especially backside reflow soldering. Together with wave soldering as well as selective soldering (a variant of wave soldering), this soldering method is most frequently applied and is known in principle from a large number of publications. Circuit boards manufactured with these soldering methods are applied in different embodiments in the measuring devices manufactured by the Endress+Hauser group of companies. The choice of applied soldering process is determined, in such case, as a rule, by the type of components arranged on the circuit board for soldering.

For example, frequently surface mountable components, so called ‘Surface Mounted Devices’, or SMD components, are used, which are soldered with the reflow soldering method. SMD components require no circuit board holes for mounting, but, instead, are soldered with their contacts directly to pads provided on the boards. SMD components equipped with solder paste are placed with automatic populator machines, pick and place machines, on pads on the circuit board and soldered in place in a single reflow process. In such case, SMD components can be placed on both surfaces of the circuit board, in that, firstly, the first surface is populated with its components. The SMD components are soldered there; then the circuit board is turned over and the second surface provided in the same manner with its SMD components. A large number of electronic components are obtainable as SMD components, which leads to a considerable reduction of manufacturing costs.

Besides SMD components, there are still plenty of special components, which as a result of their functions have greater dimensions. These components are preferably embodied as through hole technology components—THT components for short. THT components have pin-shaped connection wires, which are stuck through metallized connection bores in the circuit board. THT components are typically soldered in a wave soldering process. In such case, the circuit board is caused to travel over a so-called solder wave. The solder wave is produced by pumping liquid solder, which is located in a heated pot, through a narrow slot.

To integrate THT components into a manufacturing process dominated in large part by SMD components, preferably the method known under the name, backside reflow soldering, is used; examples of which are described in patent DE 102 11 647 B4. In such case, SMD components and THT components are arranged on the first surface of the circuit board and SMD components on the second surface of the circuit board. Then, the THT components arranged on the first surface are soldered upside down and from the second surface of the circuit board together with the SMD components arranged on the second surface in one working step in a reflow process. In this way, the backside reflow method enables economical manufacture of circuit boards previously mix populated on both sides with SMD and THT components.

To comply with the requirements of heavy metal limiting standards and regulations, any residues of lead in the measuring device should be prevented. For this reason, in increasing degree, lead-free solders and solder pastes are being used. In the case of lead-free solder pastes, the temperature applied for soldering is, as a rule, higher. It lies at about 235° C. to 265° C. for reflow soldering, and for backside reflow soldering.

Different types of manufacturing lines with reflow soldering oven and backside reflow soldering oven are known, wherein, in the present state of the art, first and foremost, reflow soldering plants with convection heating are applied. Common to all reflow soldering ovens is use of a preheat zone, a soldering zone and a cooling zone. The component to be soldered, here the circuit board to be soldered, is, in such case, transported by a transport apparatus through the different temperature zones of the soldering oven. The present invention relates to such a soldering oven with convection heating.

In the preheat zone, the solder paste-equipped component to be soldered is preheated and gradually brought to a temperature of about 160° C. On the one hand, this vaporizes a portion of solvent in the flux. The flux is used, to reduce surface oxides and to improve the flow and wetting properties of the liquid solder. Also, this can prevent a temperature lag of the assembly due to a too steep temperature rise during the soldering, so that it acts to protect the soldering. There are manufacturing lines, which make use of a preheat zone, wherein the component to be soldered is heated only on one surface and also manufacturing lines, wherein the component to be soldered is heated on both surfaces.

In the soldering zone, there then occurs further heating of the component to be soldered to a temperature, which lies above the liquidus temperature of the applied solder paste, to perform the actual soldering procedure. To achieve solder locations of high quality, it is necessary to hold the temperature of the solder joint for a maximum of 60 seconds above the liquidus temperature of the solder paste. If arranged on a circuit board to be soldered are also larger components, then the soldering zone must be operated with a temperature that lies significantly above the soldering temperature to assure within this time that also the larger components, i.e., their solder locations, reach the soldering temperature. Consequently, process temperatures of up to 300° C. are used in the soldering zone; see e.g. DE 197 417 92. In such case, the temperature profile in a particular temperature zone depends on the soldering method, the temperature sensitivity of the applied components, and the type of solder paste used. The entire soldering procedure as well as the temperature present on the surface of the circuit board are controlled in the state of the art by the residence times in the different temperature zones. The temperature zones have, in such case, in the state of the art, one or more heating elements arranged offset one after the other in the transport direction.

The exact control of the temperature present on the surface of the circuit board via the residence time is, however, not always possible. The problem lies, on the one hand, in the different heat conductivity properties of the circuit board and/or components, and, on the other hand, in a convection dependent mixture of air layers of various temperatures in the soldering oven. This convection leads lastly to uncontrollable heat conduction in the soldering oven.

An uncontrollable heat conduction is, above all, problematic, when different temperatures should be present on the first and second surfaces of the circuit board. If, for example, in the case of reflow soldering, both surfaces of the circuit board are sequentially soldered, a partial re-melting of the solder locations of the already soldered surface can lead to an undesired shifting, or slipping, of components. This undesired shifting of components can lead to an increased rejection rate in the context of quality control in the production and therewith lastly to increased production costs.

In contrast, there is in the case of backside reflow soldering the need to set stable and large temperature differences between the two surfaces of the circuit board. The control of these temperature differences is especially critical and/or especially demanding, when older components with temperature sensitive plastic portions and/or lead-free solder pastes are used with the above mentioned, high soldering temperatures. Consequently, desirable is a manufacturing line, which is suited for protective soldering with reflow and backside reflow soldering as well as being suited for a large number of components.

An object of the invention is, therefore, to provide a manufacturing line for soldering, which permits an exact control of the temperature present on the circuit board to provide a predetermined temperature profile.

The object is achieved by a manufacturing line for soldering components on a circuit board, comprising: a soldering oven having at least two temperature zones, in which a predetermined temperature profile is present, a transport apparatus, which is embodied to transport circuit boards through the temperature zones of the soldering oven in a transport direction, as well as a control system; wherein, in at least one of the temperature zones, at least two heating elements are so embodied and/or arranged that a to-be-soldered surface of circuit boards transported through the soldering oven is heated by the heating elements, wherein the heating elements are arranged in the transport direction offset one after the other, and face the surface to be soldered, wherein, in at least one of the temperature zones, at least two air circulators are provided arranged in the transport direction offset one after the other and facing the surface to be soldered, and wherein the control system is embodied so to control the heating elements and air circulators that the predetermined temperature profile in the temperature zones is present on the to-be-soldered surface of the circuit board.

The components are, in such case, for example, THT or SMD components. The surface to be soldered can, in such case, be the surface, on which the components are arranged. The surface to be soldered can, however, also be the surface lying opposite to that on which the components are arranged, such as is the case, for example, in backside reflow soldering for the upside-down soldering of THT components.

The predetermined temperature profile is, in such case, essentially a temperature/location function describing temperature as a function of location. The location is, in such case, essentially described based on the path traveled in the transport direction in the manufacturing line. The transport plane is, in such case, in parallel with the plane of the circuit board. The temperature profile describes, in such case, especially the course of temperature in the different temperature zones. According to the invention, in contrast with the state of the art, a plurality of air circulators are provided in at least one of the temperature zones arranged offset one after the other in the transport direction. The at least two air circulators are separately operable. The temperature present on the surface of the circuit board can, in such case, be set by the separately operable air circulators. In the context of the invention, firstly, at least two heating elements are provided in at least one of the temperature zones. Of course, also in each temperature zone, at least two heating elements can be provided. The number of air circulators in the context of the invention is preferably less than or equal to the number of heating elements in each temperature zone.

The heating elements arranged offset one after the other lie preferably on a line parallel to the transport direction. Also, the air circulators arranged offset one after the other lie preferably on a line parallel to the transport direction.

In principle, also a control of the temperature present on the surface would be an option. However, since convection processes in a soldering oven are highly non-linear processes, such a control of the temperature present on the circuit board would be very demanding, and, consequently, would be scarcely suitable for use in industrial manufacturing technology. For this reason, the invention relates only to an open-loop control and not an air circulator based, closed-loop control of the temperature present on the circuit board.

In order that such an open-loop control unit be possible, experience must be collected, for example, by experiments, regarding the particular embodiment of the soldering oven and/or the solder paste and/or the component to be soldered. This is possible, since the component to be soldered concerns, as a rule, standardized circuit boards and/or components (with standardized embodiments, especially with reference to the dimensions and/or materials). Also, the solder paste concerns, as a rule, standardized solder pastes. The experience gained in the experiments includes which control of the totality of the air circulators leads to which temperature on the surface of the circuit board. This experience can then be stored in the manufacturing line (e.g. in the control unit) or also in a user manual.

In a first embodiment of the invention, at least two additional heating elements in at least one of the temperature zones are so embodied and/or arranged that another surface of the circuit board is heated by the additional heating elements, wherein the other surface lies opposite to the surface to be soldered, and wherein the additional heating elements are arranged in the transport direction offset one after the other and face the other surface. The additional heating elements arranged offset one after the other lie preferably on a line parallel to the transport direction.

In an additional embodiment of the invention, in at least one of the temperature zones, two additional air circulators are provided arranged in the transport direction offset one after the other and facing the other surface. In this embodiment, there are thus both the air circulators, which face the surface to be soldered, as well as also additional air circulators, which face the other surface. In this way, there are air circulators, which face both surfaces of the circuit board, thus, for example, are arranged above and below the circuit board. Also, the additional air circulators arranged in the transport direction offset one after the other lie preferably on a line parallel to the transport direction.

The air circulators and/or the additional air circulators can, in such case, be embodied essentially the same. Also, the heating elements and/or the additional heating elements can, in such case, be embodied essentially the same.

In an additional embodiment of the invention, the control system is embodied so to control the heating elements and additional heating elements and the air circulators and the additional air circulators that the predetermined temperature profile is present in the temperature zones on the surface to be soldered and on the other surface. In this embodiment, the temperature present on the surface, or the surfaces, is thus determined by the totality of heating elements and additional heating elements and air circulators and additional air circulators. For example, by the targeted control of one air circulator and an additional air circulator, which lies opposite the air circulator in the direction perpendicular to the transport direction, the mixing of air layers in the direction perpendicular to the transport direction can be prevented. In this way, those convection processes, which lead to a mixing of air layers with different temperatures, are minimized.

In an additional embodiment of the invention, the temperature profile provides that, in at least one of the temperature zones, different temperatures are present on the surface to be soldered and on the other surface.

This is, for example, frequently the case in backside reflow soldering. In this embodiment, the temperature profile has not one temperature/location function, but, instead, two temperature/location functions, one for the surface to be soldered and one for the other surface of the circuit board. These two temperature/location functions can then be set in combination with the preceding embodiment by control of the totality of the air circulators and the additional air circulators, as well as the heating elements and the additional heating elements.

In an additional embodiment of the invention, the air circulators are controllable essentially based on speed in revolutions per minute (RPM) and/or the additional air circulator are controllable essentially based on RPM. Using RPM of the air circulators, or the additional air circulators, convection is controlled in the vicinity of the air circulators and additional air circulators. In this way, for example, the amount of air circulated, or moved, by the air circulators, or additional air circulators, is set.

In a further development of this embodiment, the temperature profile is so embodied that the temperature of the temperature profile in a first temperature zone is always greater than the temperature of the temperature profile in a second temperature zone, wherein the two temperature zones neighbor in the transport direction and wherein in both temperature zones air circulators and/or additional air circulators are provided. The RPM of the air circulators in the first temperature zone is less than or equal to RPM of the air circulators in the second temperature zone and/or RPM of the additional air circulators in the first temperature zone is less than or equal to RPM of the additional air circulators in the second temperature zone.

This embodiment concerns, thus, the control of the air circulators of temperature zones neighboring one another in the transport direction. The RPM of the air circulators or the additional air circulators is controlled depending on the surface. The temperature profile is formed such that the temperature of the temperature/location function in the first temperature zone is always greater than the temperature of the temperature/location function in the second temperature zone: The first temperature zone is thus always warmer than the second temperature zone. The first temperature zone can in reference to the transport direction be arranged in front of or behind the second temperature zone. In this embodiment, RPM of the air circulators and/or the additional air circulators is less in the warmer temperature zone. Advantageously in this embodiment, such coordination of air circulator and/or the additional air circulator RPMs prevents that air layers from neighboring, colder temperature zones are led into the warmer temperature zone.

In an additional embodiment of the invention, the soldering oven has at least three temperature zones, a preheat zone, a soldering zone and a cooling zone.

In an embodiment of the invention, the soldering oven is a reflow soldering oven.

In an embodiment of the invention, the soldering oven is a backside reflow soldering oven. In the embodiment of the backside reflow soldering oven, the soldering oven, or the manufacturing line, is embodied to turn the circuit board and to populate the circuit board on both surfaces. Of course, the soldering oven, or the manufacturing line, can, in the embodiment, reflow soldering oven, be embodied to turn the circuit board, for example, over, and to populate the circuit board, such as mentioned above, on both sides with SMD components.

In an additional embodiment of the invention, the manufacturing line is embodied for soldering with a lead-free solder paste. The soldering with a lead-free solder paste requires, especially in conjunction with backside reflow soldering and/or temperature sensitive THT components, a very exact control of the temperature present on the circuit board. The invention enables, for the first time, a lead-free backside reflow soldering, which is not possible with known manufacturing lines of the state of the art.

In an additional embodiment of the invention, the transport apparatus is embodied to transport circuit boards in the different temperature zones with different transport speeds.

In this embodiment, the temperature present on the surface of the circuit board can be supplementally controlled based on the transport speed. In a further development of this embodiment, the transport apparatus is composed of transport units, wherein in each temperature zone at least one transport unit is arranged for transporting the circuit boards with settable transport speed. The transport units can be, for example, a single or a plurality of conveyor belts.

In an additional embodiment of the invention, there are stored in the control system different operating modes, in which the manufacturing line can be operated, wherein each operating mode predetermines the temperature profile of the temperature zones, and wherein the temperature profile of a particular operating mode is matched to the soldering oven, the soldering method, the solder paste applied for soldering and/or the embodiment of the components.

Associated with the temperature profile is, in such case, depending on embodiment, the temperature/location function of the surface to be soldered and/or the other surface. The operating mode is, in such case, firstly, dependent on the soldering oven. The soldering oven is, in such case, established for the particular manufacturing line.

On the other hand, the operating mode is also dependent on the particular application, or the conditions predetermined by the user and present in the particular applications. In reference to the conditions present in the particular application, in such case, a certain operating mode stored in the control system can be selected for operating the manufacturing line.

The operating mode is, for example, dependent on the component to be soldered; especially the embodiment of its components. In such case, for example, the temperature sensitivity and the geometric dimensions of the components are of consequence. The geometric dimensions determine, in turn, the thermal conductivity of the component and the space requirement. Also the applied solder paste influences the operating mode. Another possible influence is the choice of soldering process, whether thus it is a reflow soldering or a backside soldering. Depending on which it is, different temperature profiles are required on the surface and/or the other surface. Advantageously in this embodiment, the different operating modes can be stored in the control system and selected with reference to the application.

In an especially preferred embodiment of the invention, a first operating mode provides a first temperature profile, and at least a second operating mode provides a second temperature profile different from the first temperature profile, wherein the difference between the temperatures of the two temperature profiles is essentially settable by control of the totality of the air circulators and/or the additional air circulators.

The predetermined temperature profiles thus have different temperatures. Especially advantageous in this embodiment is that the difference between the different temperature profiles is set only by control of the air circulators. The heating elements have in this embodiment essentially the same settings in the first and second operating modes. In the case of change from one operating mode into the other, consequently, only the air circulators and/or the additional air circulators are adjusted, or operated differently. The heating elements and/or the additional heating elements, in contrast, do not need to be, or only in small measure, altered. Since heating elements are, as a rule, slower to respond than air circulators, the changing, or switching, between different operating modes can occur in essentially shorter times in this embodiment. This is advantageous, since, in this way, idle times in the production are lessened and therewith costs are saved.

In a further development of this embodiment, the difference between the temperatures of the two temperature profiles is essentially settable by control of the totality of the air circulators and/or additional air circulators and the transport speed of the transport apparatus. In this further development, thus, supplementally a change of the transport speed is performed in the case of a change between operating modes. Also, this requires essentially no, or very little, conversion time between the operating modes, especially relative to conversion times, which would be required by a change of temperature of the heating elements.

The invention will now be explained in greater detail based on the appended drawing, the figures of which show as follows:

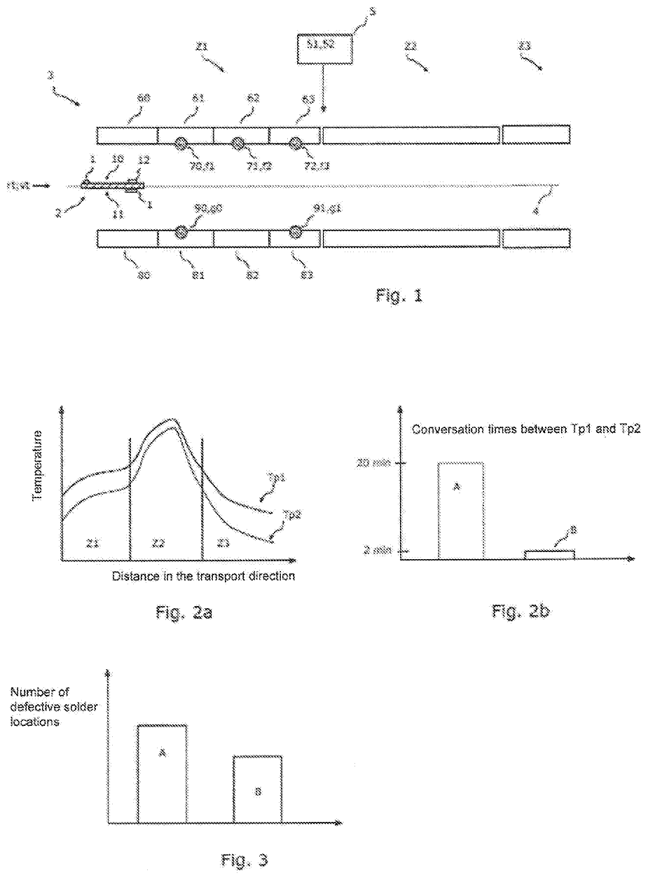

FIG. 1 a schematic illustration of the manufacturing line of the invention;

FIG. 2a different temperature profiles;

FIG. 2b conversion times between temperature profiles with the manufacturing line of the invention;

FIG. 3 the lessening of reject rate with the manufacturing line of the invention.

FIG. 1 shows a schematic illustration of the manufacturing line of the invention with a soldering oven 3 and a transport apparatus, based on which a circuit board 2 with components 1 is transported in a transport direction rt with a transport speed vt through temperature zones Z1, Z2, Z3 of the soldering oven. In this example, components 1 are arranged on a surface 10 to be soldered and on an opposite surface 11. Of course, also other embodiments are possible. The soldering oven 3 includes in this example of an embodiment three temperature zones Z1, Z2, Z3. In the example shown here, four heating elements 60, 61, 62, 63 and three air circulators 70, 71, 72 are arranged in the first temperature zone Z1 offset one after the other in the transport direction rt. Also arranged in the first temperature zone Z1 offset one after the other in the transport direction rt are four additional heating elements 80, 81, 82, 83 and two additional air circulators 90, 91. For purposes of simplification, only the heating elements and air circulators of the first temperature zone Z1 are shown in this example of an embodiment. Preferably, each temperature zone Z1, Z2, Z3 of the soldering oven 3 should have at least one heating element.

Other embodiments are, of course, possible, especially relative to the number of heating elements; the, in given cases present, additional heating elements; the air circulators and the, in given cases present, additional air circulators. The number of air circulators is in the context of the invention preferably less than or equal to the number of heating elements and, in given cases, the number of additional air circulators is preferably less than or equal to the number of additional heating elements.

The transport plane is, in such case, arranged in parallel with the plane of the circuit board 2. In such case, such as shown in this example of an embodiment, the transport plane of the transport apparatus 4 can be arranged centrally between the heating elements 60, 61, 62, 63 and the additional heating elements 80, 81, 82, 83. It is, of course, also an option that the transport plane is arranged nearer or farther from the heating elements 60, 61, 62, 63 than from the additional heating elements 80, 81, 82, 83. For example, an option is to match the separation of the heating elements 60, 61, 62, 63 or the additional heating elements 80, 81, 82, 83 from the transport plane to the dimensions of the components 1.

The invention is suited especially also for such a non-symmetric construction, since RPMs f1, f2, f3 of the air circulators 70, 71, 72 can be controlled separately from RPMs g0, g1 of the additional air circulators 90, 91.

For setting RPMs f1, f2, f3, for example, a conventional rotational speed converter is used. Stored in the control system 5 are different operating modes 51, 52. For such purpose, the control system 5 includes, for example, a programmable logic control unit (PLC), such as commonly applied in process and automation technology.

Shown schematically in FIG. 2a are different temperature profiles Tp1, Tp2, which are commonly present in reflow soldering. In the preheat zone Z1, the component to be soldered is preheated. The actual soldering process (i.e., the forming of material bonded connections) takes place in the soldering zone Z2. This is where the temperature is, as a rule, the highest. In the cooling zone Z3, there is then a cooling of the soldered item. The two temperature profiles Tp1, Tp2 can be set by the choice of operating mode 51, 52.

According to the invention, in such case, the temperature profiles Tp1, Tp2 of the different operating modes 51, 52 are achieved just by changed operation of the air circulators 70, 71, 72 and, in given cases, the additional air circulator 90, 91. In the case of equal operation of the heating elements 60, 61, 62, 63 and, in given cases, the additional heating elements 80, 81, 82, 83 the temperatures present on the surface 10 of the circuit board 2 and, in given cases, on the opposite surface 11 of the circuit board 2 can be so set that a particular temperature profile Tp1, Tp2 is present in the temperature zones Z1, Z2.

In this way, conversion times can be avoided and delays in the manufacturing significantly minimized. This is shown in FIG. 2b. There, typical conversion times between typical temperature profiles with a process optimized manufacturing line A of the state of the art are compared with conversion times of the manufacturing line B of the invention. Experiments show that conversion times can be lessened with the manufacturing line of the invention to a tenth of what they were. This is a significant advantage, since idle times in the production can be similarly lessened. Also, costs are reduced therewith.

A further advantage of the invention is that backside reflow soldering with a lead-free solder paste 12 is enabled for the first time. By air circulators 70, 71, 72 and additional air circulators 90, 91 arranged in a temperature zone Z1, Z2, Z3 offset one after the other in the transport direction rt, a mixing of air layers in the direction perpendicular to the transport plane can be prevented. In this way, a stable and large temperature difference can be established between the surface 10 to be soldered and the other surface 11.

On the other hand, the manufacturing line of the invention provides with a soldering oven 3 embodied for reflow soldering improved results in the protective soldering of groups of components 1 on circuit boards. This is shown in FIG. 3. For such a standard process, a process optimized manufacturing line A of the state of the art was compared with the manufacturing line B of the invention. In such case, the number of defective solder locations was registered. Referred to as defective solder locations in the context of the present invention are solder locations with components 1, which have slipped on the circuit board 2 or have only partly melted solder joints. The experimental investigations show that the number of defective solder locations with the manufacturing line B of the invention can be lessened by about 30% in comparison with the manufacturing line A of the state of the art.

### LIST OF REFERENCE CHARACTERS

1 a component
2 circuit board
3 soldering oven
4 transport apparatus
5 control system
51,52, . . . operating modes
60,61, . . . heating elements
70,71, . . . air circulators
80,81, . . . additional heating elements
90,91, . . . additional air circulators
10 surface to be soldered
11 other surface
12 solder paste
Z1,Z2, . . . temperature zones
rt transport direction
Tp,Tp1,Tp2, . . . temperature profiles
f0, f1,f2,f3 RPMs of the air circulators
g0,g1,g2,g3 . . . RPMs of the additional air circulators
vt transport speed

1-15. (canceled)

16. A manufacturing line for soldering components on a circuit board, the manufacturing line comprising:
a soldering oven including at least two temperature zones having a predetermined temperature profile along a transport direction through the soldering oven, wherein at least one of the at least two temperature zones includes at least two air circulators offset from one another in the transport direction;
a transport apparatus embodied to transport circuit boards through the at least two temperature zones of the soldering oven in the transport direction; and
a control system, wherein:
in at least one of the at least two temperature zones, at least two heating elements are disposed such that a to-be-soldered surface of each circuit board transported through the soldering oven is heated by the at least two heating elements;
the at least two heating elements are offset from one another in the transport direction and are directed toward the to-be-soldered surface;
the at least two air circulators are directed toward the to-be-soldered surface; and
the control system is configured to control the at least two heating elements and the at least two air circulators such that the to-be-soldered surface of each circuit board is heated according to the predetermined temperature profile.

17. The manufacturing line of claim 16, wherein at least two additional heating elements are disposed in at least one of the at least two temperature zones such that an opposing surface of each circuit board is heated by the at least two additional heating elements, wherein the opposing surface is opposite the to-be-soldered surface, and wherein the at least two additional heating elements are offset from one another in the transport direction and are directed toward the opposing surface.

18. The manufacturing line of claim 17, wherein, in at least one of the temperature zones, two additional air circulators are offset from one another in the transport direction and are directed toward the opposing surface.

19. The manufacturing line of claim 18, wherein the control system is further configured to control the at least two heating elements, at least two additional heating elements, the at least two air circulators and the two additional air circulators such that both the to-be-soldered surface and the opposing surface of each circuit board are heated according to the predetermined temperature profile.

20. The manufacturing line of claim 19, wherein, according to the predetermined temperature profile, the to-be-soldered surface and the opposing surface of each circuit board are heated to different temperatures in at least one of the at least two temperature zones.

21. The manufacturing line of claim 18, wherein the at least two air circulators are controlled using revolutions per minute (RPM) and/or the two additional air circulators are controlled using RPM.

22. The manufacturing line of claim 21, wherein:
according to the predetermined temperature profile, a temperature of a first temperature zone is greater than a temperature of a second temperature zone, the first temperature zone adjacent the second temperature zone;
both the first temperature zone adjacent the second temperature zone includes air circulators and/or additional air circulators; and
the RPM of the air circulators in the first temperature zone is less than or equal to the RPM of the air circulators in the second temperature zone, and/or the RPM of the additional air circulators in the first temperature zone is less than or equal to the RPM of the additional air circulators in the second temperature zone.

23. The manufacturing line of claim 16, wherein the soldering oven has at least three temperature zones, defining as a preheat zone, a soldering zone and a cooling zone.

24. The manufacturing line of claim 16, wherein the soldering oven is a reflow soldering oven.

25. The manufacturing line of claim 16, wherein the soldering oven is a backside reflow soldering oven.

26. The manufacturing line of claim 16, wherein the manufacturing line is embodied for soldering with a lead-free solder paste.

27. The manufacturing line of claim 16, wherein the transport apparatus is configured to transport the circuit boards through each of the at least two temperature zones at different transport speeds.

28. The manufacturing line of claim 16, wherein:
the control system is configured with different operating modes stored therein for operating the manufacturing line;
each operating mode includes a predetermined temperature profile of the at least two temperature zones; and
a temperature profile of a given operating mode corresponds to the soldering oven, a type of solder paste applied for soldering in the solder oven, and/or types of the components.

29. The manufacturing line of 28, wherein:
a first operating mode includes a first temperature profile;
a second operating mode includes a second temperature profile different from the first temperature profile; and
a difference between temperatures of the first temperature profile and the second temperature profile is controlled, at least in part, by the at least two air circulators.

30. The manufacturing line of claim 29, wherein the difference between the temperatures of the first temperature profile and the second temperature profile is further controlled, at least in part, by a transport speed of the transport apparatus.
